(19) United States
(12) Patent Application Publication
(10) Pub. No.: US 2025/0340982 A1
(43) Pub. Date: Nov. 6, 2025

(54) METHODS AND APPARATUS WITH DUAL EXHAUST PLENUMS

(71) Applicant: ASM IP Holding B.V., Almere (NL)

(72) Inventors: Ankit Kimtee, Phoenix, AZ (US); Jereld Lee Winkler, Gilbert, AZ (US)

(21) Appl. No.: 19/194,369

(22) Filed: Apr. 30, 2025

Related U.S. Application Data
(60) Provisional application No. 63/642,436, filed on May 3, 2024.

(51) Int. Cl. C23C 16/44; C23C 16/455; C23C 16/52

(52) U.S. Cl. CPC C23C 16/4412; C23C 16/45557; C23C 16/52; C23C 16/45565

(57) ABSTRACT

Various embodiments of the present technology may provide an apparatus having two separate exhaust plenums. The apparatus may include a top portion having at least one inlet and a first exhaust plenum and a second exhaust plenum. The apparatus may further include a bottom portion having a plurality of first exhaust through-holes coupled to the first exhaust plenum and a plurality of second exhaust through-holes coupled to the second exhaust plenum.

### CROSS-REFERENCE TO RELATED APPLICATIONS

This application is a nonprovisional of, and claims priority to and the benefit of, U.S. Provisional Patent Application No. 63/642,436, filed May 3, 2024 and entitled “METHODS AND APPARATUS WITH DUAL EXHAUST PLENUMS,” which is hereby incorporated by reference herein.

### FIELD OF INVENTION

The present disclosure generally relates to a method and apparatus with dual exhaust plenums. More particularly, the present disclosure relates to a showerhead having two separate exhaust paths.

### BACKGROUND OF THE TECHNOLOGY

Reaction chambers used in semiconductor manufacturing typically utilize an exhaust system to remove unused precursor and co-reactant from the reaction space. In conventional systems, a single exhaust plenum and exhaust line are used to remove the unused precursor and co-reactant.

### SUMMARY OF THE INVENTION

Various embodiments of the present technology may provide an apparatus having two separate exhaust plenums. The apparatus may include a top portion having at least one inlet and a first exhaust plenum and a second exhaust plenum. The apparatus may further include a bottom portion having a plurality of first exhaust through-holes coupled to the first exhaust plenum and a plurality of second exhaust through-holes coupled to the second exhaust plenum.

According to one aspect, an apparatus, comprises: a top portion comprising: an inlet plenum; a first exhaust plenum; and a second exhaust plenum; and a bottom portion coupled to the top portion and comprising: a first surface and an opposing second surface, and a showerhead region comprising a plurality of inlet through-holes extending between the first and second surfaces; a plurality of first exhaust through-holes fluidly coupled to the first exhaust plenum; and a plurality of second exhaust through-holes fluidly coupled to the second exhaust plenum.

In an embodiment, the first and second exhaust plenums are arranged concentric with the inlet plenum, and the first exhaust plenum is isolated from the second exhaust plenum.

In an embodiment, the first exhaust plenum has a first volume and the second exhaust plenum has a second volume that is larger than the first volume.

In an embodiment, the apparatus further comprises a sealing mechanism disposed within the second exhaust plenum and configured to isolate the second exhaust plenum from the reaction space, wherein the sealing mechanism comprises a ring and an actuator coupled to the ring.

In an embodiment, the apparatus further comprises: a first exhaust line coupled to the first exhaust plenum and extending outwards from the first portion; and a second exhaust line coupled to the second exhaust plenum and extending outwards from the second portion.

In an embodiment, the first exhaust plenum has a first volume and the second exhaust plenum has a second volume that is substantially equal to the first volume, and wherein the first exhaust through-hole has a first diameter and the second exhaust through-hole has a second diameter that is substantially equal to the first diameter.

In an embodiment, the apparatus further comprises a first isolation valve coupled to the first exhaust plenum and a second valve coupled to the second exhaust plenum.

In an embodiment, the apparatus further comprises a first pump coupled downstream from the first isolation valve and a second pump coupled downstream from the second isolation valve.

In an embodiment, the first exhaust through-hole has a first diameter and the second exhaust through-hole has a second diameter that is larger than the first diameter.

In an embodiment, the first and second exhaust through-holes are arranged radially outward from the showerhead region.

In an embodiment, each exhaust through-hole from the plurality of first exhaust holes converges with a respective exhaust through-hole from the plurality of second exhaust through-holes at the second surface of the showerhead plate.

In an embodiment, the second exhaust through-hole is vertically-oriented and the first exhaust through-hole is angled relative to the second exhaust through-hole.

In another aspect, an apparatus comprises: a top portion comprising: an inner apparatus comprising an inlet plenum; and an outer apparatus separated from the inner apparatus by an air gap, and comprising: a first exhaust plenum; and a second exhaust plenum; and a bottom portion coupled to the top portion and comprising: a showerhead plate comprising a first surface and an opposing second surface, and a showerhead region comprising a plurality of through-holes extending between the first and second surfaces; a plurality of first exhaust through-holes fluidly coupled to the first exhaust plenum; and a plurality of second exhaust through-holes fluidly coupled to the second exhaust plenum; wherein the first exhaust through-hole has a first diameter and the second exhaust through-hole has a second diameter that is larger than the first diameter.

In an embodiment, the apparatus further comprises a sealing mechanism disposed within the second exhaust plenum and configured to isolate the second exhaust plenum from the reaction space.

In an embodiment, each exhaust through-hole from the plurality of first exhaust holes converges with a respective exhaust through-hole from the plurality of second exhaust through-holes at the second surface of the showerhead plate; and the second exhaust through-hole is vertically-oriented and the first exhaust through-hole is angled relative to the second exhaust through-hole.

In yet another aspect, an apparatus comprises: a top portion comprising: an inlet plenum; a first exhaust plenum; and a second exhaust plenum; a bottom portion coupled to the top portion and comprising: a showerhead plate comprising a first surface and an opposing second surface, and a showerhead region comprising a plurality of through-holes extending between the first and second surfaces; a plurality of first exhaust through-holes fluidly coupled to the first exhaust plenum; a plurality of second exhaust through-holes fluidly coupled to the second exhaust plenum; wherein each exhaust through-hole from the plurality of first exhaust holes converges with a respective exhaust through-hole from the plurality of second exhaust through-holes at the second surface of the showerhead plate; and a sealing mechanism disposed within the second exhaust plenum and configured to isolate the second exhaust plenum from the reaction space.

In an embodiment, the first and second exhaust plenums are arranged concentric with the inlet plenum, and the first exhaust plenum is isolated from the second exhaust plenum.

In an embodiment, the sealing mechanism comprises a ring-shaped plug formed from a metal material or a ceramic material.

In an embodiment, the apparatus further comprises: a pressure sensor to measure the pressure in the reaction space; and an actuator coupled to the sealing mechanism and configured to actuate the sealing mechanism based on data from the pressure sensor.

In an embodiment, the first exhaust through-hole has a first diameter and the second exhaust through-hole has a second diameter, wherein the first diameter is 20-25% of the second diameter.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a cross-sectional view of a reactor in accordance with embodiments of the present technology;

FIG. 3 is a top view of a gas channel plate in accordance with embodiments of the present technology;

FIG. 4 is a top view of the gas channel plate in accordance with embodiments of the present technology;

FIG. 5 is a top view of a showerhead plate in accordance with embodiments of the present technology;

FIG. 6 is a top view of the showerhead plate in accordance with embodiments of the present technology;

FIG. 7 is a block diagram of an exhaust system in accordance with an embodiment of the present technology;

FIG. 8 is a block diagram of an alternative exhaust system in accordance with an embodiment of the present technology; and

FIG. 9 is a cross-sectional view of a portion of the system in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, susceptors, and temperature sensors.

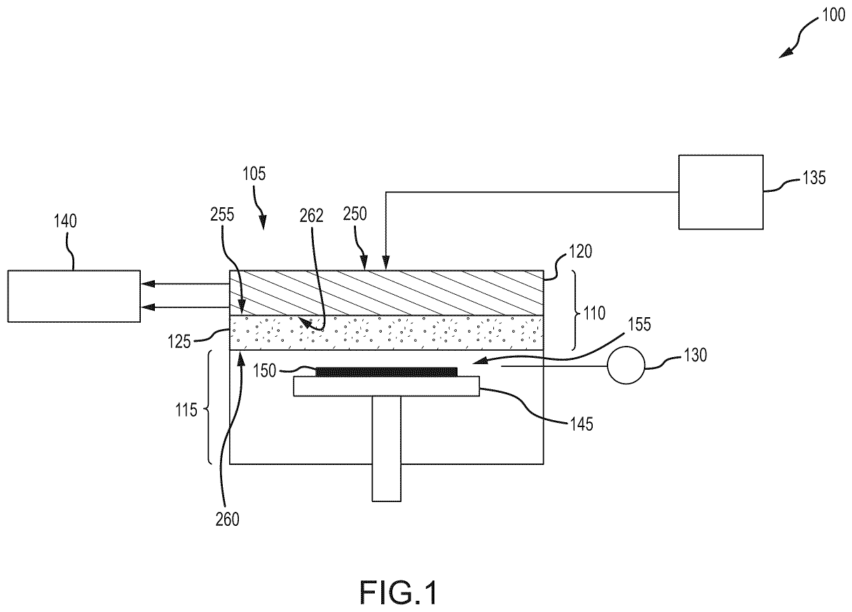

Referring to FIG. 1, an exemplary system 100 may comprise a reactor 105 configured to perform processing on an object to be processed, such as a substrate 150 (e.g., a wafer). For example, the reactor 105 may be configured to perform heating, deposition, etching, polishing, ion implantation, and/or other processing on the object to be processed. In some embodiments, the reactor 105 may be configured to perform a movement function, a vacuum sealing function, an exhaust function. In some embodiments, the reactor 105 may perform and atomic layer deposition (ALD) process or a chemical vapor deposition (CVD) process.

In an exemplary embodiment, the reactor 105 may comprise a reaction chamber 115 comprising a reaction space 155 above and/or around the substrate 150. For example, the reaction chamber 115 may comprise sidewalls and a bottom coupled to the sidewalls.

The system 100 may further comprise a pressure sensor 130 configured to measure a pressure in the reaction chamber 115, in particular, to measure a pressure in the reaction space 155. For example, the pressure sensor 130 may be disposed in or near the reaction space 155. The pressure sensor 130 may comprise any suitable pressure sensor, such as a pressure transducer that measures the pressure and converts the measured pressure into an electrical signal.

In various embodiments, the system 100 may further comprise a substrate mounting unit disposed within the reaction chamber 115 of the reactor 105. The substrate mounting unit may comprise a susceptor 145 for supporting the substrate 150 and a heater (not shown) for heating the substrate 150 supported by the susceptor 145. The heater may be embedded within the susceptor 145. The substrate mounting unit may further comprise a pedestal to support the susceptor 145. For loading/unloading of the substrate, the substrate mounting unit may be configured to be vertically movable (up and down) by being connected to a driving unit (not shown). The susceptor 145 may be disposed in or adjacent the reaction space 155. For example, the susceptor 145 may be arranged to position the substrate 150 in the reaction space 155.

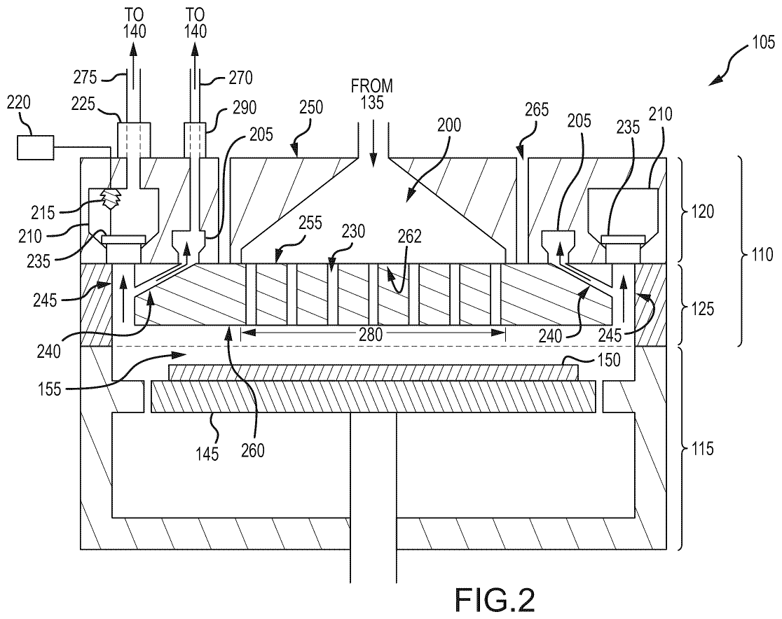

In various embodiments, and referring back to FIGS. 1 and 2, the reactor 105 may further comprise a gas distribution system 110 for delivering a vapor into the reaction chamber 115. In an exemplary embodiment, the gas distribution system 110 is arranged above the susceptor 145. The gas distribution system 110 may comprise a top portion 120 (i.e., a gas channel plate) and a bottom portion 125 (i.e., a showerhead plate). The top and bottom portions 120, 125 may be in direct contact with each other. For example, the top portion 120 may comprise a first surface 250 and an opposite, parallel second surface 255, and the bottom portion 125 may comprise a first surface and an opposing, parallel second surface 260. A surface (e.g., the second surface 255) of the top portion 120 may be direct contact with a surface (e.g., the first surface 262) of the bottom portion 125. In some embodiments, the first and second portions 120, 125 may be coupled together with a fastener, such as a screw or the like.

In various embodiments, the gas distribution system 110 may be arranged adjacent to the reaction chamber 115. For example, the gas distribution system 110 may be arranged on the sidewalls of the reaction chamber 115, opposite the bottom of the reaction chamber 115. In some embodiments, the gas distribution system 110 may be fastened to the sidewalls, however, in other cases, the gas distribution system 110 may merely rest on the sidewalls of the reaction chamber 115. In various embodiments, the gas distribution system 110 together with the reaction chamber 115 sidewalls form an enclosed space, including the reaction space 155.

In various embodiments, the top portion 120 may further comprise a first exhaust plenum 205 and a second exhaust plenum 210. The first exhaust plenum 205 may be isolated from the second exhaust plenum 210. In an exemplary embodiment, the first exhaust plenum has a first volume and the second exhaust plenum has a second volume that is larger than the first volume.

In alternative embodiments, the first and second exhaust plenums have approximately (+/−5%) the same volume.

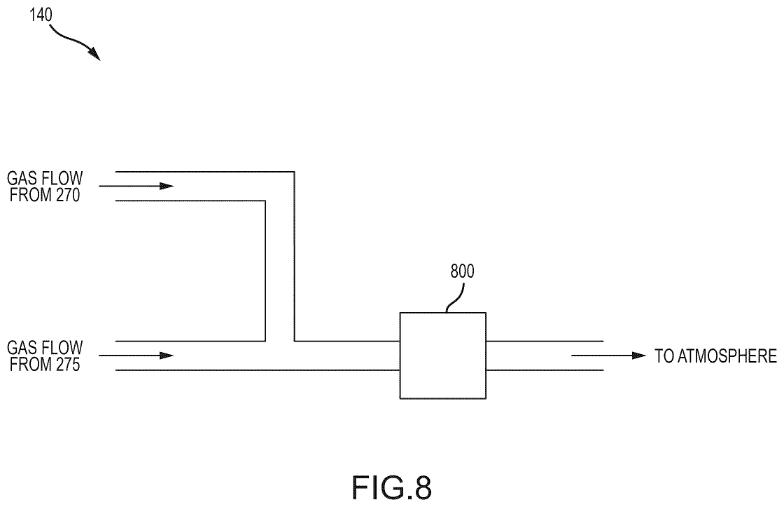

The first exhaust plenum 205 may comprise an inlet at the second surface 255 and an outlet 270 at the first surface 250. The second exhaust plenum 210 may comprise an inlet at the second surface 255 and an outlet 275 at the first surface 250. The outlets 270, 275, may be coupled to an exhaust system 140. For example, gas may flow from the plenums 205, 210 through the respective outlets and into the exhaust system 140. In various embodiments, and referring to FIGS. 1, 2, and 7-8, the exhaust system 140 may comprise a foreline and a pump (e.g., a vacuum pump). In some embodiments, the exhaust system 140 may comprise a single pump 800 coupled to both plenum outlets 270, 275 via a single foreline (e.g., as illustrated in FIG. 8).

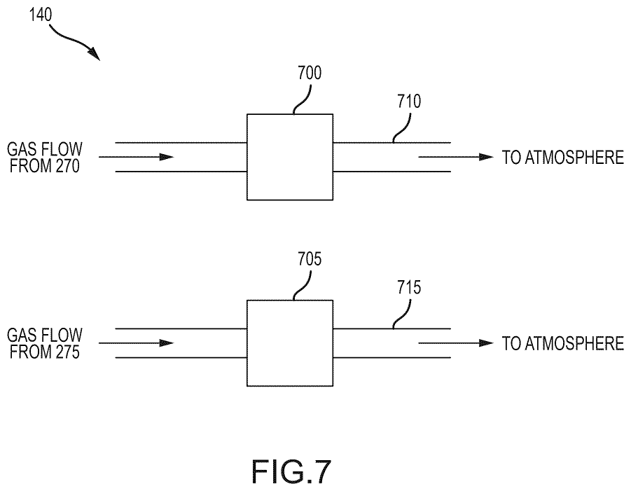

In other embodiments, each plenum outlet 270, 275 may be coupled to a dedicated foreline and pump. For example, and referring to FIG. 7, the outlet 270 of the first exhaust plenum 205 may be coupled to a first pump 700 and a first foreline 710, and the outlet 275 of the second exhaust plenum 210 may be coupled to a second pump 705 and a second foreline 715. The first and second pumps 700, 705 and their respective forelines 710, 715 may be physically isolated from each other. In the present case, each foreline 710, 715 exhausts to atmosphere.

In various embodiments, the first and second exhaust plenums 205, 210 may be arranged concentric with the inlet plenum. For example, the first exhaust plenum 205 may have a ring shape with a first diameter that surrounds and is larger than the inlet plenum 200, and the second exhaust plenum 205 may have ring shape with a second diameter that surrounds and is larger than the first diameter of the first exhaust plenum 205. Alternatively, the first exhaust plenum 205 (i.e., the plenum with the smaller volume) may be arranged outside of and surrounding the second exhaust plenum 210 (i.e., the plenum with the larger volume).

In an exemplary embodiment, the second exhaust plenum 210 (i.e., the larger volume plenum) may comprise a funnel-shaped region having sidewalls that angle inwards, wherein the larger diameter portion of the funnel-shaped region is above the smaller diameter region.

In various embodiments, the top portion 120 may be formed as a single unit. In other embodiments, the top portion 120 may be formed from multiple sections. For example, a first section may comprise the inlet plenum 200, and a second section may comprise the first and second exhaust plenums. An air gap 265 may separate the first section from the second section.

In various embodiments, the system 100 may further comprise a vessel 135 configured to contain a chemical (i.e., a precursor). The vessel 135 may be configured to hold a solid or a liquid chemical, and may further be configured to transform the solid or liquid into a vapor. The vessel 135 may be coupled to the gas distribution system 110. For example, the system 100 may further comprise various gas conduits and/or valves to flow the vapor from the vessel 135 into the gas distribution system 110.

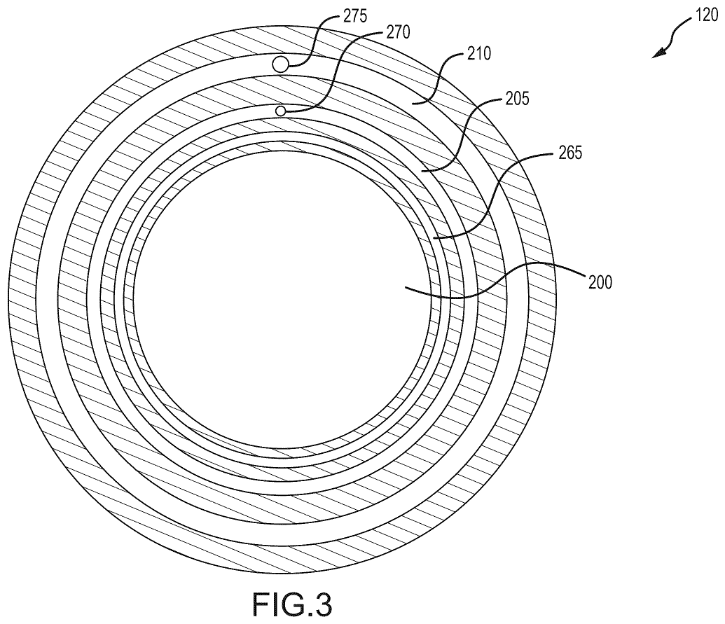

In various embodiments, and referring to FIGS. 2-6, the top portion 120 of the gas distribution system 110 may comprise an inlet plenum 200 configured to receive vapor from the vessel 135. In addition, the bottom portion 125 may comprise a plurality of inlet through-holes 230 that extend through the first surface 262 and the second surface 260. The plurality of inlet through-holes 230 may contain approximately 1000-1200 through-holes. The plurality of inlet through-holes 230 may be arranged within a central region 280 (also referred to as a showerhead region) of the bottom portion 125. The inlet plenum 200 may be in fluid communication with the plurality of inlet through-holes 230. For example, the vapor that flow into the inlet plenum 200 from the vessel 135 may continue to flow through the plurality of through-holes 230. The plurality of inlet through-holes 230 may be in fluid communication with the reaction space 155. For example, the vapor may flow through the plurality of inlet through-holes 230 and into the reaction space 155.

In addition, the bottom portion 125 of the gas distribution system 110 may further comprise a plurality of first exhaust through-holes 240 (e.g., 20-100 holes, in particular, 65-80) fluidly coupled to the first exhaust plenum 205, and a plurality of second exhaust through-holes 245 (e.g., 20-100 holes, in particular 65-80) fluidly coupled to the second exhaust plenum 210.

In various embodiments, the number of first exhaust holes 240 is equal to the number of second exhaust holes 245. However, in other embodiments, the number of first exhaust holes 240 is less than the number of second exhaust holes 245.

In addition, each first exhaust through-hole 240 may have a first diameter and each second exhaust through-hole 245 has a second diameter that is larger than the first diameter. For example, the first exhaust hole 240 diameter may be 20-25% the size of the second exhaust hole 245 diameter. For example, the second exhaust hole 245 may be 4-5 mm and the first exhaust hole 240 may be approximately 1 mm.

In alternative embodiments, the diameter of the first and second exhaust through-holes 240, 245 may be substantially the same (e.g., +/−5%).

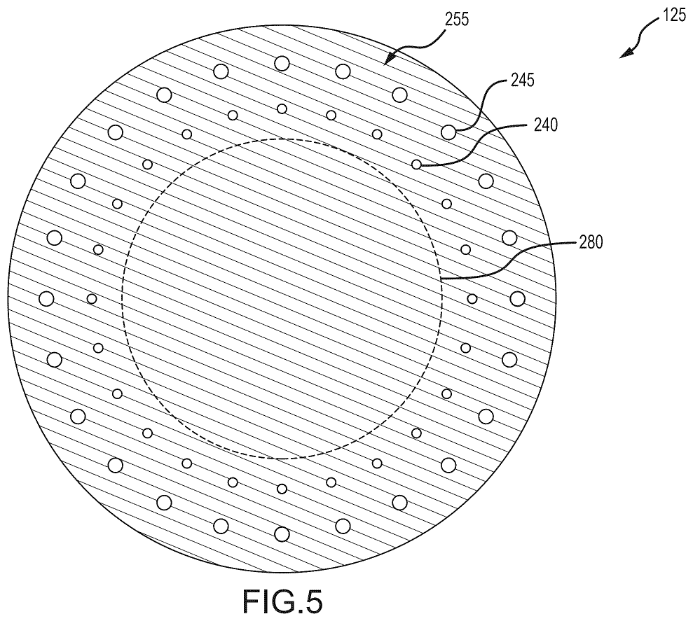

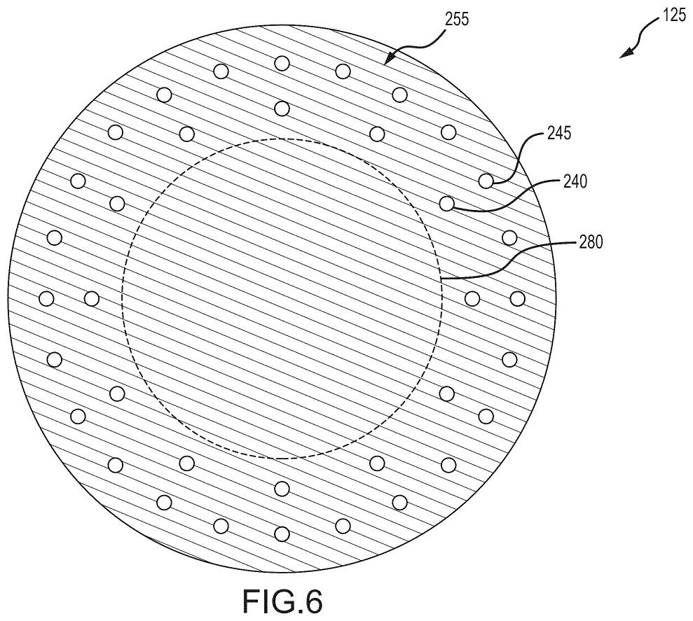

The plurality of first exhaust through-holes 240 may each have a first opening at the first surface 255 of the bottom portion 125 of the gas distribution system 110. The first openings of the plurality of first exhaust through-holes 240 may be arranged in a ring pattern (e.g., as illustrated in FIGS. 5 and 6). In addition, the first openings of the plurality of first exhaust through-holes 240 may be positioned to be in fluid communication with the first exhaust plenum 205. In particular, the first openings of the plurality of first exhaust through-holes 240 may align with the inlet of the first exhaust plenum 205. In an exemplary embodiment, the first exhaust through-holes 240 and the first exhaust plenum 205 allow gas to flow constantly through them and into the exhaust system 140. In other words, there are no mechanism within the first exhaust through-holes 240 and the first exhaust plenum 205 that would completely block flow of the gas.

In addition, the first openings of the plurality of first exhaust through-holes 240 may be arranged radially outward from the plurality of inlet through-holes 230. Each of the first exhaust through-holes 240 may have a second opening that fluidly connects to a through-hole from the plurality of second through-holes 245. In other words, each first exhaust through-hole 240 may converge with or otherwise join a respective second exhaust through-hole 245.

The plurality of second exhaust through-holes 245 may have a first opening at the first surface 255 of the bottom portion 125 and a second opening adjacent to the reaction space 155. For example, the second openings may be arranged outside of the central region 280. In addition, the first openings of the second exhaust through-holes 245 may be concentric with the first exhaust through-holes 240 (e.g., as illustrated in FIGS. 5 and 6). In addition, the first openings of the plurality of second exhaust through-holes 245 may be positioned to be in fluid communication with the second exhaust plenum 210. In particular, the first openings of the plurality of second exhaust through-holes 245 may align with the inlet of the second exhaust plenum 210.

In an exemplary embodiment, each second exhaust through-hole 245 may be vertically oriented within the bottom portion 125. In addition, each of the first exhaust through-holes 240 may be angled with respect to a respective second exhaust through-hole 245. For example, the first exhaust through-hole 240 may be angled in a range 20 degrees to 60 degrees, such as 45 degrees. In other words, when viewed along a cross-section, the first and second exhaust through-holes 240, 245 may form a branched shape, with the first exhaust through-hole 240 extending from (i.e., branching off of) the second exhaust through-hole 45 (e.g., as illustrated in FIG. 2).

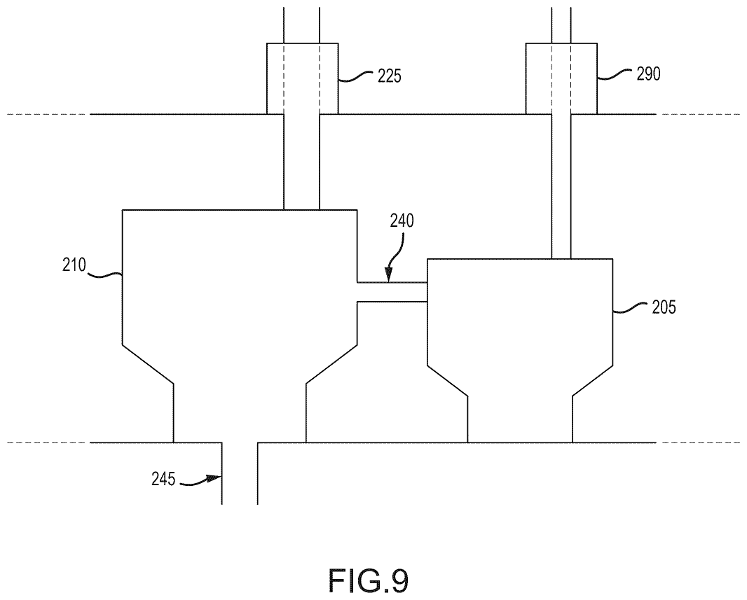

In an alternative embodiment, and referring to FIG. 9, the plurality of first through-holes may connect the second exhaust plenum 210 to the first exhaust plenum 205.

In some cases, and referring to FIG. 6, where there are less first exhaust through-holes than 240 second exhaust through-holes, some of the second exhaust through-holes 245 may not be branched and contain only one flow path from the reaction space 155 to the second plenum 210.

In various embodiments, the system 100 may further comprise a sealing mechanism configured to seal off or otherwise block gas flow from the reaction space 155 to at least of the first and second plenums. In an exemplary embodiment, the sealing mechanism may comprise a ring-shaped plug 235 disposed within the larger volume exhaust plenum (e.g., the second exhaust plenum 210). The plug 235 may have a feature with a diameter that is substantially the same as the second exhaust plenum 210. The plug 235 may be formed from a metallic/metal material, such as elemental aluminum, a ceramic material (e.g., aluminum oxide), quartz, sapphire, or any other suitable material that is capable of providing a seal and withstanding high temperatures (e.g., 150° C. to 500° C.).

In an exemplary embodiment, the sealing mechanism may further comprise an actuator 220 coupled to the plug 235 and configured to actuate (i.e., move up and down) the plug 235. The actuator 220 may comprise any device or system suitable for generating a mechanical movement, such as a stepper motor or the like. In an exemplary embodiment, the sealing mechanism comprises a plurality of actuators, such as a first actuator 220(a), a second actuator 220(b), and a third actuator 220(c). The actuators 220(a), 220(b), 220(c) may be attached to the plug 235 at equal distances from each other, for example, one every 120 degrees. In the down position, as illustrated in FIG. 2, the plug 235 may seal off flow from the plurality of second exhaust through-holes 245 into the second exhaust plenum 210. For example, the plug 235 may rest on and be in direct contact with the angled sidewalls of the second plenum 210. In contrast, in the up position, the plug 235 may allow flow into the second exhaust plenum 210.

In an exemplary embodiment, the sealing mechanism may further comprise a bellow 215 disposed inside the second exhaust plenum 210. The bellow 215 may couple the actuator 220 to the plug 235 and facilitate movement of the plug 235. For example, the actuator 220 may move to expand or contract the bellow 215. The expansion or contraction of the bellow 215, in turn, pushes or pulls the plug 235 to the down or up positions, respectively.

In various embodiments, the system 100 may further comprise a first valve 290 coupled to the outlet 270 of the first exhaust plenum 205, and in particular, between the exhaust system 140 and the first exhaust plenum 205. The first valve 290 may comprise any suitable valve, such as an isolation valve.

The system 100 may further comprise a second valve 225 coupled to the outlet 275 of the second exhaust plenum 210, and in particular, between the exhaust system 140 and the second exhaust plenum 210. The second valve 225 may comprise a fast acting, isolation valve.

In exemplary embodiments, either the sealing mechanism or the second valve 225 is utilized to block flow through the second exhaust plenum 210. For example, in one embodiment, only the second valve 225 is utilized without the use of the sealing mechanism and visa versa.

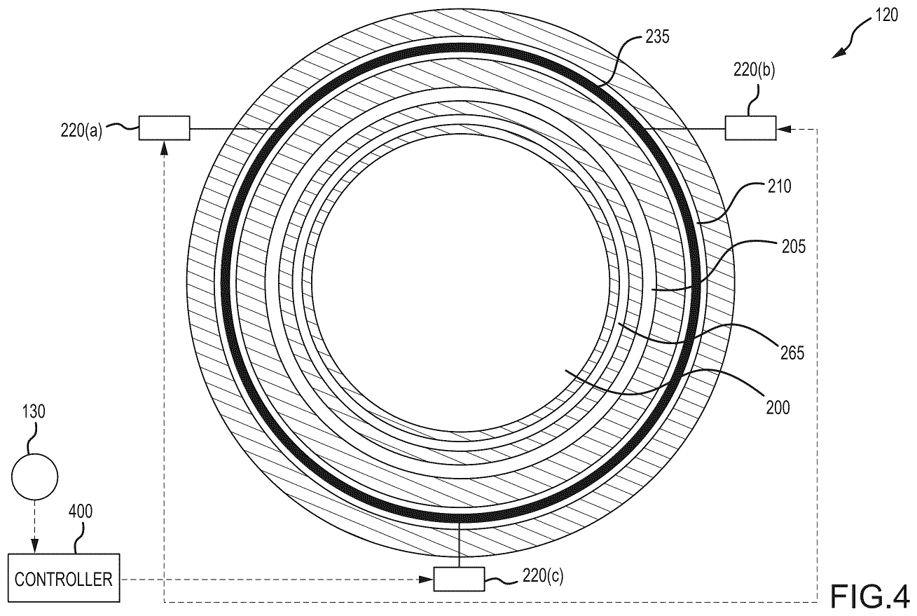

In various embodiments, and referring to FIG. 4, the system 100 may further comprise a controller 400 configured to control operation of various components within the system such as the first and second valves 290, 225 and the actuators 220(a), 220(b), 220(c). For example, the controller 400 may be electrically and/or commutatively coupled to the first and second valves 290, 225 and the actuators 220(a), 220(b), 220(c) and may transmit a control signal to each one that indicates an operation mode. For example, a first control signal may open or close the second valve 225 and a second control signal may induce movement of the actuator. In some cases, the controller 400 may operate the actuators 220 and plug 235 according to a predetermined pulse and purge cycle.

The controller 400 may also receive information, data, or signals from other components, such as the pressure sensor 130, and the controller 400 may operate the actuators 220(a), 220(b), 220(c) based on a measured pressure from the pressure sensor 130. For example, the controller 400 may receive a measured pressure from the pressure sensor 130 and determine if the measured pressure is at a desired pressure or desired pressure range. If the measured pressure is not at the desired pressure or pressure range, the controller 400 may transmit a signal to actuator 220 to move it up or down. Moving the actuator 200 to move the plug 235 to the up position will decrease the pressure in the reaction space 155, while moving the actuator to move the plug 235 to the down position will increase the pressure in the reaction space 155.

In some embodiments, maintaining controllable outflow is desired. In this case, the first exhaust plenum 205 may be smaller than the second exhaust plenum 210 and the first plurality of through-holes 240 is smaller in diameter than the plurality of second through-holes 245. Furthermore, the exhaust system 140 may be configured as illustrated in FIG. 8, with a single pump 800.

In some embodiments, separating the exhaust of various precursors is desired. In this case, the first exhaust plenum 205 may be the same volume as the second exhaust plenum 210, and the first plurality of through-holes 240 have the same diameter as the plurality of second through-holes 245. In this case, the sealing mechanism may be omitted and the first and second valves 290, 225 may be utilized to block gas flow through the respective exhaust plenum 205, 210. Furthermore, the exhaust system 140 may be configured as illustrated in FIG. 7 with two separate pumps 700, 705.

In operation, and referring to FIGS. 1-7, the system 100 may be configured to perform atomic layer deposition (ALD), wherein the precursor from the vessel 135 is pulsed into the reaction space via the gas distribution system 110 and then purged using an inert gas, such as argon. During the pulsing step, the plug 235 may be placed in the down position to seal off the second exhaust plenum 210 from the reaction space 155. During the purging step, the plug 235 may be raised to the up position to allow gas from the reaction space 155 to flow into the second exhaust plenum 210. The movement of the plug 235 may coincide with the timing for pulsing and purging via the controller 400.

In an alternative operation, during the pulsing step, the second valve 225 may be closed to block gas flow through the second exhaust plenum 210. During the purge step, the second valve 225 may be open. In this case, the first valve 290 may be closed during a pulsing step and open during a purge step. The operation of the first and second valves 290, 225 may alternate. For example, the first valve 290 may be opened during a purge of a first precursor and the second valve 225 may be opened during a purge of a second precursor that is different from the first precursor.

In yet another alternative operation, during the pulsing step, the second valve 225 may be closed to block gas flow through the second exhaust plenum 210. During the purge step, the second valve 225 may be open. In this case, the first valve 290 is omitted or left open during both the pulsing and purging steps.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the

What is claimed is:

1. An apparatus, comprising:
a top portion comprising:
an inlet plenum;
a first exhaust plenum; and
a second exhaust plenum; and
a bottom portion coupled to the top portion and comprising:
a first surface and an opposing second surface, and
a showerhead region comprising a plurality of inlet through-holes extending between the first and second surfaces;
a plurality of first exhaust through-holes fluidly coupled to the first exhaust plenum; and
a plurality of second exhaust through-holes fluidly coupled to the second exhaust plenum.

2. The apparatus according to claim 1, wherein the first and second exhaust plenums are arranged concentric with the inlet plenum, and the first exhaust plenum is isolated from the second exhaust plenum.

3. The apparatus according to claim 1, wherein the first exhaust plenum has a first volume and the second exhaust plenum has a second volume that is larger than the first volume.

4. The apparatus according to claim 1, further comprising a sealing mechanism disposed within the second exhaust plenum and configured to isolate the second exhaust plenum from the reaction space, wherein the sealing mechanism comprises a ring and an actuator coupled to the ring.

5. The apparatus according to claim 1, further comprising:
a first exhaust line coupled to the first exhaust plenum and extending outwards from the first portion; and
a second exhaust line coupled to the second exhaust plenum and extending outwards from the second portion.

6. The apparatus according to claim 1, wherein the first exhaust plenum has a first volume and the second exhaust plenum has a second volume that is substantially equal to the first volume, and wherein the first exhaust through-hole has a first diameter and the second exhaust through-hole has a second diameter that is substantially equal to the first diameter.

7. The apparatus according to claim 6, further comprising a first isolation valve coupled to the first exhaust plenum and a second valve coupled to the second exhaust plenum.

8. The apparatus according to claim 7, further comprising a first pump coupled downstream from the first isolation valve and a second pump coupled downstream from the second isolation valve.

9. The apparatus according to claim 1, wherein the first exhaust through-hole has a first diameter and the second exhaust through-hole has a second diameter that is larger than the first diameter.

10. The apparatus according to claim 1, wherein the first and second exhaust through-holes are arranged radially outward from the showerhead region.

11. The apparatus according to claim 1, wherein each exhaust through-hole from the plurality of first exhaust holes converges with a respective exhaust through-hole from the plurality of second exhaust through-holes at the second surface of the showerhead plate.

12. The apparatus according to claim 1, wherein the second exhaust through-hole is vertically-oriented and the first exhaust through-hole is angled relative to the second exhaust through-hole.

13. An apparatus, comprising:
a top portion comprising:
an inlet plenum;
a first exhaust plenum; and
a second exhaust plenum, wherein the first exhaust plenum has a first volume and the second exhaust plenum has a second volume that is larger than the first volume; and
a bottom portion coupled to the top portion and comprising:
a showerhead plate comprising a first surface and an opposing second surface, and a showerhead region comprising a plurality of through-holes extending between the first and second surfaces;
a plurality of first exhaust through-holes fluidly coupled to the first exhaust plenum;
and
a plurality of second exhaust through-holes fluidly coupled to the second exhaust plenum;
wherein the first exhaust through-hole has a first diameter and the second exhaust through-hole has a second diameter that is larger than the first diameter.

14. The apparatus according to claim 13, further comprising a sealing mechanism disposed within the second exhaust plenum and configured to isolate the second exhaust plenum from the reaction space.

15. The apparatus according to claim 13, wherein:
each exhaust through-hole from the plurality of first exhaust holes converges with a respective exhaust through-hole from the plurality of second exhaust through-holes at the second surface of the showerhead plate; and
the second exhaust through-hole is vertically-oriented and the first exhaust through-hole is angled relative to the second exhaust through-hole.

16. An apparatus, comprising:
a top portion comprising:
an inlet plenum;
a first exhaust plenum; and
a second exhaust plenum;
a bottom portion coupled to the top portion and comprising:
a showerhead plate comprising a first surface and an opposing second surface, and a showerhead region comprising a plurality of through-holes extending between the first and second surfaces;
a plurality of first exhaust through-holes fluidly coupled to the first exhaust plenum;
a plurality of second exhaust through-holes fluidly coupled to the second exhaust plenum; wherein each exhaust through-hole from the plurality of first exhaust holes converges with a respective exhaust through-hole from the plurality of second exhaust through-holes at the second surface of the showerhead plate; and
a sealing mechanism disposed within the second exhaust plenum and configured to isolate the second exhaust plenum from the reaction space.

17. The apparatus according to claim 16, wherein the first and second exhaust plenums are arranged concentric with the inlet plenum, and the first exhaust plenum is isolated from the second exhaust plenum.

18. The apparatus according to claim 16, wherein the sealing mechanism comprises a ring-shaped plug formed from a metal material or a ceramic material.

19. The apparatus according to claim 16, further comprising:
a pressure sensor to measure the pressure in the reaction space; and
an actuator coupled to the sealing mechanism and configured to actuate the sealing mechanism based on data from the pressure sensor.

20. The apparatus according claim 16, wherein the first exhaust through-hole has a first diameter and the second exhaust through-hole has a second diameter, wherein the first diameter is 20-25% of the second diameter.
